(19) United States
(12) Patent Application Publication
(10) Pub. No.: US 2025/0079978 A1
(43) Pub. Date: Mar. 6, 2025

(54) ELECTROMAGNETIC COMPATIBILITY FILTER, DC-DC ELECTRICAL CONVERTER COMPRISING SUCH A FILTER, MOBILITY VEHICLE COMPRISING SUCH A CONVERTER OR SUCH A FILTER, AND METHOD FOR MANUFACTURING SUCH A FILTER

(71) Applicant: Valeo eAutomotive Germany GmbH, Erlangen (DE)

(72) Inventors: David CRAVO, Cergy Pontoise (FR); Olivier GILET, Cergy Pontoise (FR)

(73) Assignee: Valeo eAutomotive Germany GmbH, Erlangen (DE)

(21) Appl. No.: 18/824,567

(22) Filed: Sep. 4, 2024

(30) Foreign Application Priority Data
Sep. 4, 2023 (FR) 2309273

(51) Int. Cl. H02M 1/44; H02M 3/00

(52) U.S. Cl. CPC H02M 1/44; H02M 3/003

(57) ABSTRACT

A filter includes first, second and third conductors; a first capacitor connected between the first conductor and the third conductor; a second capacitor connected between the second conductor and the third conductor; and a third capacitor connected between the first conductor and the second conductor. A pin of the first capacitor is situated higher, in relation to a vertical axis along which a clamp of the second conductor projects upwards, than a pin of the second capacitor, such that an oblique axis along which a first clamp and a second clamp of the third conductor project in opposing directions and the vertical axis form an angle between them of less than 80°, preferably less than 70°, for example 65°.

### TECHNICAL FIELD OF THE INVENTION

The present invention relates to an electromagnetic compatibility filter, a DC-DC electrical converter comprising such a filter, a mobility vehicle comprising such a converter or such a filter and a method for manufacturing such a filter.

A mobility vehicle is, for example, a motor-driven land vehicle, a train, an aircraft or a drone. A motor-driven land vehicle is, for example, a motor vehicle, a motorbike, a motorized bicycle or a motorized wheelchair.

### Technological Background

The prior art discloses an electromagnetic compatibility filter, comprising:
a first conductor;
a second conductor comprising a clamp projecting along an axis referred to as the vertical axis in a direction referred to as the upward direction;
a third conductor comprising:
   a first clamp and a second clamp projecting along the same axis referred to as the oblique axis but in opposing directions, the first and second clamps being situated higher than the clamp of the first conductor,
   a connection terminal situated lower than the first and second clamps, and
   an elongate body connecting the connection terminal to the first and second clamps;
a first capacitor connected between the first conductor and the third conductor, the first capacitor comprising a pin projecting along a first axis substantially perpendicular to the vertical axis and to the oblique axis, this pin of the first capacitor being gripped by the first clamp of the third conductor;
a second capacitor connected between the second conductor and the third conductor, the second capacitor comprising a pin projecting along a second axis substantially parallel to the first axis, this pin of the second capacitor being gripped by the second clamp of the third conductor; and
a third capacitor connected between the first conductor and the second conductor, the third capacitor comprising a pin projecting along a third axis, substantially parallel to the first and second axes, the pin of the third capacitor being gripped by the clamp of the first conductor, the connection terminal of the third conductor being situated lower, in relation to the vertical axis, than this pin of the third capacitor.

During manufacture of the filter, the clamp of the first conductor is closed onto its associated pin by a tool, in particular a fixing clamp having two elements designed to be positioned respectively to either side of this clamp. The clamp may be a gripping clamp, in which case the elements are designed to move towards each other in order to mechanically push the two branches of the clamp respectively so that they grip the associated pin. Alternatively, or indeed additionally, the clamp may be a welding clamp, in which case the elements form electrodes for passing a current through the clamp to be closed and the associated pin in order to weld them together.

Therefore, in order to leave sufficient space for these elements, the elongated body of the third conductor must pass at a distance from the clamp, increasing the overall space requirement of the filter.

It may therefore be desirable to provide an electromagnetic compatibility filter that can be produced using a conventional tool and that has a small space requirement.

### SUMMARY OF THE INVENTION

An electromagnetic compatibility filter is therefore proposed, comprising:
a first conductor;
a second conductor comprising a clamp projecting along an axis referred to as the vertical axis in a direction referred to as the upward direction;
a third conductor comprising:
   a first clamp and a second clamp projecting along the same axis referred to as the oblique axis but in opposing directions, the first and second clamps being situated higher than the clamp of the first conductor,
   a connection terminal situated lower than the first and second clamps, and
   an elongated body connecting the connection terminal to the first and second clamps;
a first capacitor connected between the first conductor and the third conductor, the first capacitor comprising a pin projecting along a first axis substantially perpendicular to the vertical axis and to the oblique axis, this pin of the first capacitor being gripped by the first clamp of the third conductor;
a second capacitor connected between the second conductor and the third conductor, the second capacitor comprising a pin projecting along a second axis substantially parallel to the first axis, this pin of the second capacitor being gripped by the second clamp of the third conductor; and
a third capacitor connected between the first conductor and the second conductor, the third capacitor comprising a pin projecting along a third axis, substantially parallel to the first and second axes, the pin of the third capacitor being gripped by the clamp of the first conductor, the connection terminal of the third conductor being situated lower, in relation to the vertical axis, than this pin of the third capacitor;
   characterized in that the pin of the first capacitor is situated higher, in relation to the vertical axis, than the pin of the second capacitor, so that the oblique axis and the vertical axis form an angle between them of less than 80°, preferably less than 70°, for example 65°.

Therefore, as a result of the invention, the elongated body can start off at an angle at the first and second clamps, and therefore move away from the clamp of the third conductor so as to pass at a sufficient distance from the latter, while keeping the second capacitor close to the third capacitor.

The invention may further comprise one or more of the following optional features, in any technically feasible combination.

Optionally, the first clamp of the third conductor is higher than the second clamp of the third conductor.

Also optionally, the capacitors have respective housings of generally parallelepiped shape with top faces perpendicular to the vertical axis, the top face of the first capacitor extending higher than the top face of the second capacitor and the top face of the third capacitor extending below the top face of the second capacitor.

Also optionally, the first capacitor has another pin parallel to the first pin, the second capacitor has another pin parallel to the first pin, a first plane defined by the two pins of the first capacitor and a second plane defined by the two pins of the second capacitor being substantially parallel, the first plane extending above the second plane.

Also optionally, the elongated body has a straight end portion from which the clamps of the third conductor project substantially perpendicularly, this straight end portion extending horizontally away from the clamp of the first conductor, following this straight end portion from the clamps of the third conductor.

A method is also proposed for manufacturing an electromagnetic compatibility filter according to the invention, comprising:
obtaining an electromagnetic compatibility filter, comprising:
   a first conductor,
   a second conductor comprising a clamp projecting along an axis referred to as the vertical axis in a direction referred to as the upward direction,
   a third conductor comprising: a first clamp and a second clamp projecting along the same axis referred to as the oblique axis but in opposing directions, the first and second clamps being situated higher than the clamp of the first conductor, a connection terminal situated lower than the first and second clamps, and an elongated body connecting the connection terminal to the first and second clamps,
   a first capacitor connected between the first conductor and the third conductor, the first capacitor comprising a pin projecting along a first axis substantially perpendicular to the vertical axis and to the oblique axis,
   a second capacitor connected between the second conductor and the third conductor, the second capacitor comprising a pin projecting along a second axis substantially parallel to the first axis,
   a third capacitor connected between the first conductor and the second conductor, the third capacitor comprising a pin projecting along a third axis, parallel to the first and second axes, the connection terminal of the third conductor being situated lower, in relation to the vertical axis, than this pin of the third capacitor,
   the pin of the first capacitor being situated higher, in relation to the vertical axis, than the pin of the second capacitor, so that the oblique axis and the vertical axis form an angle between them of less than 80°, preferably less than 70°, for example 65°; and
for the clamp of the second conductor, positioning two elements respectively to either side of the clamp, one of the elements extending between the clamp and the elongated body of the third conductor, and using the elements so that the clamp grips the pin of the third capacitor; and
for each of the first and second clamps of the third conductor, positioning two elements respectively to either side of the clamp and using the elements so that the clamp grips the pin of the first capacitor and the pin of the second capacitor respectively.

Optionally, using the elements comprises bringing the elements closer to each other.

Also optionally, using the elements comprises using the elements as electrodes for passing a current through the clamp and the associated pin in order to weld them together.

A DC-DC electrical converter is also proposed, comprising:
an electrical conversion circuit designed to convert a DC input voltage into a DC output voltage;
an input or output connector, comprising two flat pins, one positive and the other negative, designed to receive the input voltage or to supply the output voltage; and
an electromagnetic compatibility filter according to the invention, in which the first and second conductors are respectively connected to the two pins, and in which the third connector is connected to an electrical ground.

Also proposed is a mobility vehicle comprising an electromagnetic compatibility filter according to the invention or a DC-DC electrical converter according to the invention.

### BRIEF DESCRIPTION OF THE FIGURES

The invention will be better understood by means of the following description, which is given merely by way of an example and with reference to the appended drawings, in which:

FIG. 1 is a simplified view of a mobility vehicle in which the invention may be implemented,

FIG. 2 is a simplified three-dimensional view of a DC-DC electrical converter of the mobility vehicle of FIG. 1,

FIG. 3 is a three-dimensional view of a connector of the converter of FIG. 2,

FIG. 4 is a three-dimensional view of the connector of FIG. 3, from a different viewing angle and without a magnetic torus,

FIG. 5 is a three-dimensional view of an electromagnetic compatibility filter associated with the connector of FIGS. 3 and 4,

FIG. 6 is a three-dimensional view of the electromagnetic compatibility filter, isolated from the connector,

FIG. 7 is a view of the electromagnetic compatibility filter showing the locations of elements of a tool for fixing clamps,

FIG. 8 is a view similar to that of FIG. 7 without the vertical offset of two capacitors,

FIG. 9 is a three-dimensional view of the connector of FIGS. 3 and 4 and of another connector of the DC-DC electrical converter,

FIG. 10 is a three-dimensional view of the other connector and an associated electromagnetic compatibility filter,

FIG. 11 is a series of three-dimensional views illustrating the successive steps of a method for manufacturing the other connector shown in FIGS. 9 and 10.

### DETAILED DESCRIPTION OF THE INVENTION

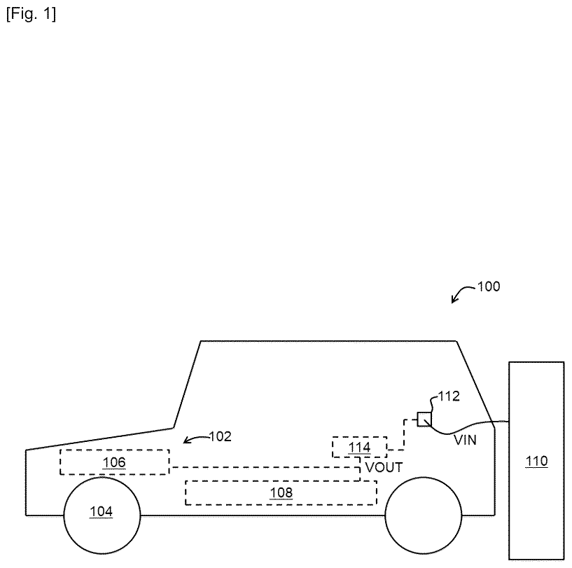

A mobility vehicle 100 in which the invention may be used will now be described in reference to FIG. 1.

The mobility vehicle 100 comprises a propulsion system 102, for example drive wheels 104 and an electric motor 106 designed to drive the drive wheels 104. The mobility vehicle 100 further comprises a battery 108 designed to electrically power the electric motor 106.

In order to recharge the battery 108 at a charging station 110 connected to an electrical distribution network (not shown), the mobility vehicle 100 further comprises an electrical socket 112 designed to be connected to the charging station 110, as well as a DC-DC electrical converter 114 connected between the electrical socket 112 and the battery 108, in order to convert an input voltage VIN received through the electrical socket 112 from the charging station 110 into an output voltage VOUT supplied to the battery 108.

Hereinafter in the description, the arrangement of the various elements of the converter 114 will refer to an arbitrary reference frame comprising a left-right X-axis, a bottom-top Y-axis and a front-back Z-axis.

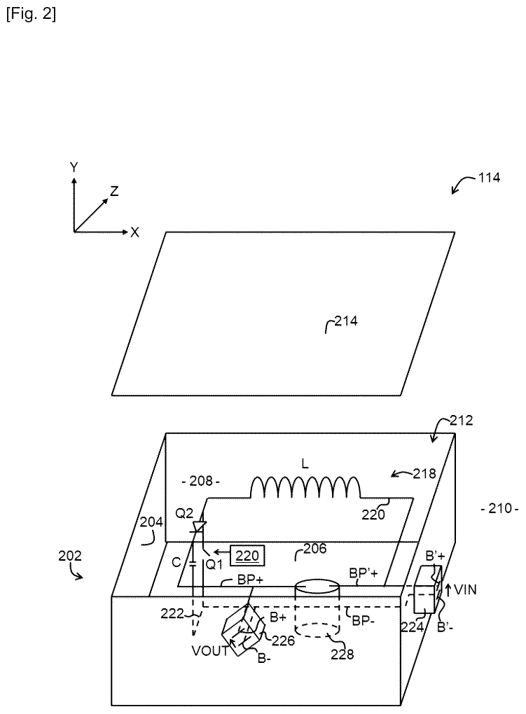

The converter 114 will now be described in greater detail in reference to FIG. 2.

The converter 114 comprises, first and foremost, a housing 202 comprising side walls 204 and a bottom 206, together defining an interior space 208 inside the housing 202 and an exterior space 210 outside the housing 202. The side walls 204 may also define, opposite the bottom 206, a top opening 212. In this case, the housing 202 may further comprise a cover 214 designed to close the top opening 212.

The converter 114 further comprises an electrical conversion circuit 218 extending inside the interior space 208 of the housing 202. The electrical conversion circuit 218 is designed to convert the input voltage VIN into the output voltage VOUT. For example, the converter 114 may be a boost converter or a step-up converter, in which case the conversion circuit 218 comprises, for example, a positive branch 220 and a negative branch 222, having an input side and an output side. The conversion circuit 218 comprises an inductor L on the positive branch, and a switch Q1 and a capacitor C, in parallel with each other between the positive branch 220 and the negative branch 222, on output side in relation to the inductor L, and another switch Q2 on the positive branch, between the switch Q1 and the capacitor C, for example a diode passing towards the capacitor C (with its cathode on the side of the capacitor C). The converter 114 then further comprises a control circuit 220 designed to control the switch Q to carry out the conversion.

In order to receive the input voltage VIN, the converter 114 further comprises an input connector 224 that can be accessed from the exterior space 210 so as to be connected to the external socket 112 by an electrical connection (not shown) that has, at one of its ends, a connector that matches the input connector 224. The input connector 224 thus comprises two input pins B′+, B′−: the first pin B′+ is referred to as the positive pin, for receiving the positive potential of the input voltage VIN, and the second pin B′− is referred to as the negative pin, for receiving the negative potential of the input voltage VIN.

In order to supply the output voltage VOUT, the converter 114 further comprises an output connector 226 that can be accessed from the exterior space 210 in order to be connected to the battery 108 by an electrical connection (not shown) that has, at one of its ends, a connector that matches the output connector 226. The output connector 226 therefore comprises two output pins B+, B−: the first pin B+ is referred to as the positive pin, for supplying the positive potential of the output voltage VOUT and the second pin B− is referred to as the negative pin, for supplying the negative potential of the output voltage VOUT.

In order to connect the negative potentials together, the converter 114 comprises a second main busbar, referred to as the negative main busbar, BP−, connecting the negative input pin B′− and the negative output pin B-together, and to the negative line 222 of the conversion circuit 218.

The converter 114 further comprises a positive input main busbar BP′+ connecting the positive input pin B′+ to the input side of the positive branch 220 of the conversion circuit 218, and a first main busbar, referred to as the positive output main busbar, BP+, connecting the positive output pin B+ to the output side of the positive branch 220 of the conversion circuit 218.

The converter 114 may further comprise a switch 228 for selectively connecting and disconnecting the positive main busbars BP+, BP′+. This allows the conversion circuit 218 to be short-circuited so that the output voltage VOUT is equal to the input voltage VIN. This function is useful, for example, when the charging station 110 supplies an input voltage VIN that is already at the voltage required to charge the battery 108.

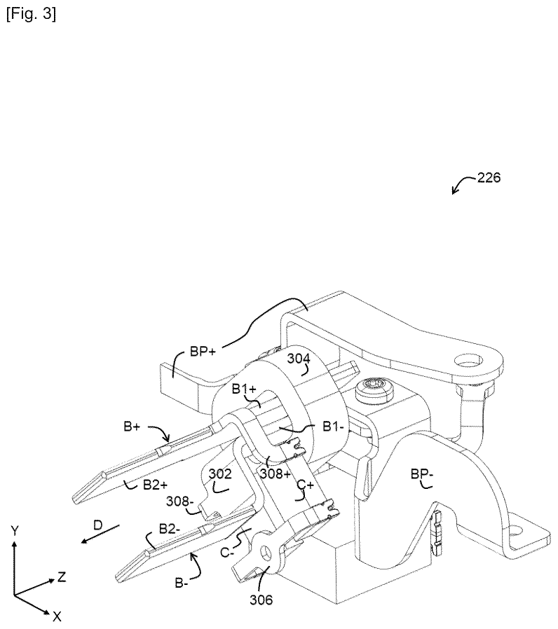

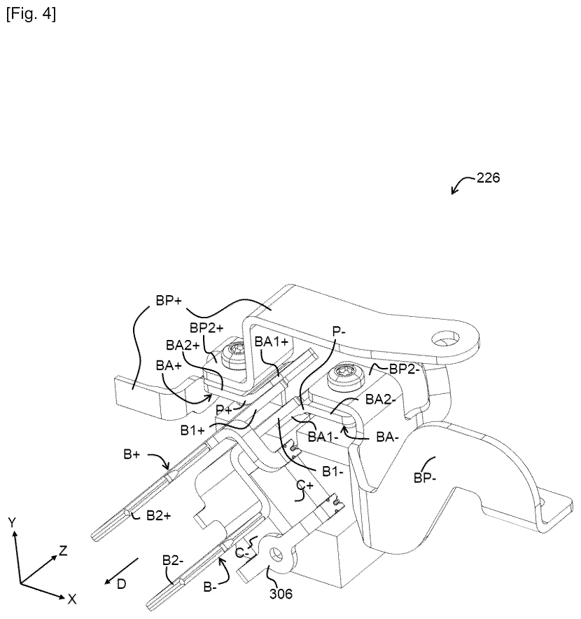

The output connector 226 will now be described in greater detail in reference to FIGS. 3 and 4.

In reference to FIG. 3, the output pins B+, B− respectively comprise, for example, two flat busbars, for example with a thickness of between 1 mm and 5 mm, for example 4 mm, each having a flat fixing portion B1+, B1− and a flat end portion B2+, B2−. The end portions B2+, B2− project, for example, towards the exterior space 210 along an axis D (in the forward direction in the example shown) and are designed to be connected along this axis D to the connector that matches the output connector 226. In other embodiments, the geometry of the end portions B2+, B2− could be a non-flat geometry, for example being the geometry of a rod with a circular cross section projecting along the axis D.

The flat fixing portions B1+, B1− extend substantially parallel, for example to within 1°, opposite each other, for example less than 10 mm apart, for example 4 mm apart. Similarly, the flat end portions B2+, B2− extend substantially parallel, for example to within 1°, opposite each other, but further apart than the flat fixing portions B1+, B1−, for example at least twice as far apart, for example between 20 mm and 30 mm apart, for example 25.7 mm apart. For example, one of the output pins B+, B− (for example, the positive output pin B+, as in the example shown) is flat, whereas the other of the output pins B+, B− (for example, the negative connection pin B−, as in the example shown) has a junction 302 between the end portion B2− and the fixing portion B1−, this junction 302 having two bends, for example, formed by bending the connection pin B-across its width.

The output connector 226 further comprises a first electromagnetic compatibility filter. This first filter comprises, for example, first and foremost, a magnetic torus 304 surrounding the output pins B+, B− and, more specifically, the fixing portions B1+, B1−, due to the limited space between them. The first filter further comprises, for example, two capacitors C+, C− connected between a busbar 306 connected to an electrical ground (for example, the housing 202) and the positive output pin B+ and the negative output pin B−, respectively. For example, the positive output pin B+ comprises a tab 308+ extending from the flat busbar to the capacitor C+. Similarly, the negative output pin B− may comprise a tab 308− extending from the flat busbar to the capacitor C−. These tabs 308+, 308− are situated between the magnetic torus 304 and the end portions B2+, B2− of the output pins B+, B−.

In reference to FIG. 4, the output connector 226 further comprises two auxiliary busbars BA+, BA−. The first BA+ is referred to as the positive auxiliary busbar and is interposed between the positive pin B+ and the positive main busbar BP+. The second BA− is referred to as the negative auxiliary busbar and is interposed between the negative pin B− and the negative busbar BP−.

Therefore, each auxiliary busbar BA+, BA− comprises a first flat portion BA1+, BA1− fixed to the positive pin B+ and the negative pin B− respectively and, more specifically, to the respective fixing portion B1+, B1− thereof. The flat portions BA1+, BA1− of the auxiliary busbars BA+, BA− are, for example, pressed and fixed against faces of the fixing portions B1+, B1−. For example, the fixing portions B1+, B1− have opposing faces (facing each other) and outer faces, on the other side from the opposing faces. Therefore, the flat portions BA1+, BA1− of the auxiliary busbars BA+, BA− are, for example, pressed and fixed against these outer faces (as in the example shown).

Each auxiliary busbar BA+, BA-further comprises a second flat portion BA2+, BA2−. These second flat portions BA2+, BA2− are substantially parallel to each other, for example to within 1°, for example being coplanar. Depending on the orientation of the output pins B+, B− about their axis D, each portion BA2+, BA2− may extend in the continuation of the first flat portion BA1+, BA1− (in which case the auxiliary busbars BA+, BA− are flat) or at a non-flat angle (as in the example shown). In the latter case, each auxiliary busbar BA+, BA− has, for example, a bend P+, P− between the portions BA1+, BA2+ and BA1−, BA2−, substantially parallel to the axis D, for example to within 1°.

Flat portions BP2+, BP2− of the respective main busbars BP+, BP− are respectively pressed and fixed against the second portions BA2+, BA2− of the auxiliary busbars BA+, BA−. Since the second portions BA2+, BA2− extend in parallel, they may be fixed in a similar manner, in particular along the same fixing axis, irrespective of the orientation of the output pins B+, B− about the axis D. In particular, when this fixing operation is carried out by screwing (as in the example shown), the screwing operation may be carried out along the axis perpendicular to the second portions BA2+, BA2−, vertically in the example shown. This screwing axis may also be used for other screws of the converter 114. Thus, the same tool may be used to carry out all of these screwing operations, irrespective of the orientation of the pins B+, B− about their axis D.

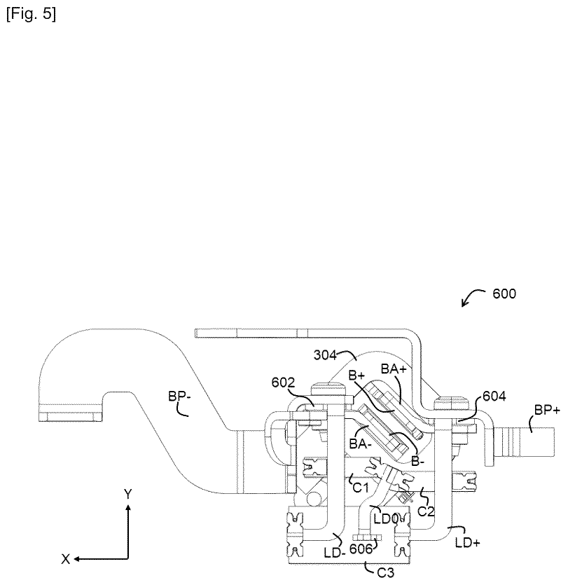

In reference to FIG. 5, the converter 114 further comprises a second electromagnetic compatibility filter 600 for the output connector 226.

This electromagnetic compatibility filter 600 comprises, first and foremost, a negative busbar LD− connected to the negative main busbar BP−. To this end, the negative busbar LD− comprises, for example, a fixing terminal 602 fixed to the negative main busbar BP−, for example by the same screw as the negative auxiliary busbar BA−. The electromagnetic compatibility filter 600 further comprises a positive busbar LD+ connected to the positive main output busbar BP+. To this end, the busbar LD+ comprises, for example, a fixing terminal 604 fixed to the positive main output busbar BP+, for example by the same screw as the positive auxiliary busbar BA+. The electromagnetic compatibility filter 600 further comprises a ground busbar LD0 connected to the electrical ground, for example to the housing 202. To this end, the ground busbar LD0 comprises a fixing terminal 606 fixed to the electrical ground.

The electromagnetic compatibility filter 600 further comprises a capacitor C1 connected between the negative busbar LD− and the ground busbar LD0, a capacitor C2 connected between the positive busbar LD+ and the ground busbar LD0, and a capacitor C3 connected between the positive busbar LD+ and the negative busbar LD−. All of the capacitors C1, C2, C3 have, for example, respective housings of generally parallelepiped shape with horizontal top faces, parallel to each other and perpendicular to the Y-axis.

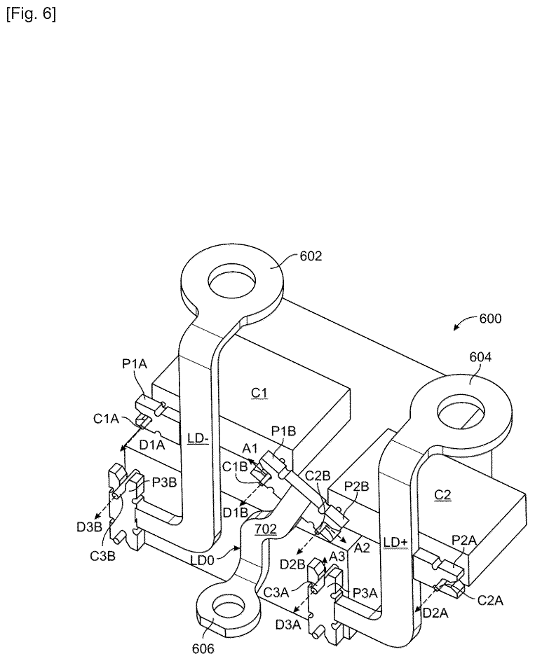

In reference to FIG. 6, in order to be connected, the capacitor C1 comprises two pins C1A, C1B projecting along axes D1A, D1B parallel to the Z-axis in the example shown. Therefore, the negative busbar LD-comprises a clamp P1A gripping the pin C1A and the ground busbar LD0 has a clamp P1B gripping the pin C1B. The clamp P1B projects, i.e., opens, along an axis referred to as the oblique axis and in a direction A1 along this axis.

Similarly, in order to be connected, the capacitor C2 comprises two pins C2A, C2B projecting along axes D2A, D2B. Therefore, the positive busbar LD+ comprises a clamp P2A gripping the pin C2A and the ground busbar LD0 has a clamp P2B gripping the pin C2B. The clamp P2B projects, i.e., opens, along the same axis, for example to within 1°, as the axis of the clamp P1B, and in a direction A2. The clamps P1B and P2B are positioned head-to-tail, i.e., the directions A1, A2 are opposing directions.

Similarly, in order to be connected, the capacitor C3 comprises two pins C3A, C3B (each of which can be duplicated, as in the example shown) projecting in forward directions D3A, D3B. Thus, the positive busbar LD+ has a clamp P3A gripping the pin C3A. This clamp P3A projects, i.e., opens, along the vertical Y-axis in the upward direction A3. The negative busbar LD− also has a clamp P3B that projects, i.e., opens, along the vertical Y-axis in the upward direction A3 and grips the pin C3B.

The ground conductor LD0 comprises an elongated body 702 extending downwards from the clamps P1B, P2B, at least as far as the pin C3A. For example, the terminal 606 of the ground conductor LD0 is situated lower than this pin C3A, so that the elongated body 702 passes to the side of the pin C3A and between the pins C3A and C3B.

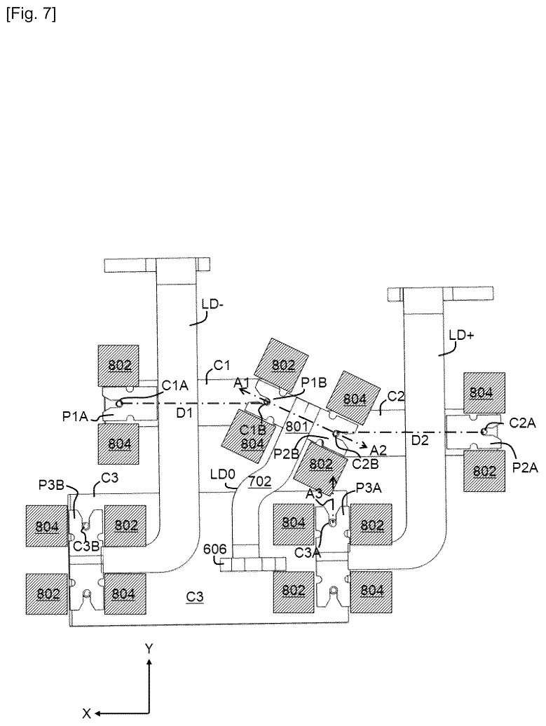

However, in reference to FIG. 7, when manufacturing the electromagnetic compatibility filter 600, each clamp P1A, P1B, P2A, P2B, P3A, P3B is closed onto its associated pin C1A, C1B, C2A, C2B, C3A, C3B by a tool, in particular a fixing clamp having two elements 802, 804 designed to be respectively positioned to either side of the clamp P1A, P1B, P2A, P2B, P3A, P3B. The fixing clamp may be a gripping clamp, in which case the elements are designed to move towards each other in order to mechanically push the two branches of the clamp P1A, P1B, P2A, P2B, P3A, P3B, respectively, so that they grip the associated pin C1A, C1B, C2A, C2B, C3A, C3B. The fixing clamp may also be an electric welding clamp, in which case the elements 802, 804 additionally or alternatively form electrodes for passing a current through the clamp P1A, P1B, P2A, P2B, P3A, P3B and the associated pin C1A, C1B, C2A, C2B, C3A, C3B in order to weld them together.

Therefore, in order to leave sufficient space for these elements 802, 804, the elongated body of the ground busbar LD0 needs to pass at a distance from the clamp P3A.

Furthermore, in order for the electromagnetic compatibility filter 600 to be as compact as possible, it is desirable for the capacitors C1 and C2, which extend above the capacitor C3, to be as close as possible to the latter.

In order to satisfy these two constraints, the capacitor C1 is positioned in such a way that its pin C1B is situated higher than the pin C2B of the second capacitor C2. Therefore, the opposing directions A1, A2 and the direction A3 together form an angle of less than 80°, preferably less than 70°, for example 65°, which allows the elongated body 702 to have a straight end portion 801, from which the clamps P1B, P2B project substantially perpendicularly, for example to within 1°, and which is angled vertically away from the clamp P3A. It is therefore possible to maintain a distance between the clamp P3A and the elongated body 702 that is sufficient for the elements 802, 804 (in particular the element 804) of the tool to pass, while keeping the capacitor C2 low, close to the capacitor C3.

For example, the capacitor C1 is positioned in such a way that its top face extends higher, i.e., at a greater height, than the top face of the capacitor C2. For example, the height of the top face of the capacitor C1 is at least 5 mm, preferably at least 10 mm, higher than the height of the top face of the capacitor C2.

Also by way of example, the pins of each capacitor C1, C2 define a straight line D1, D2. These two straight lines D1, D2 are substantially parallel, for example to within 1°, the line D1 being above the line D2, for example at least 5 mm above it, for example between 5 mm and 10 mm above it.

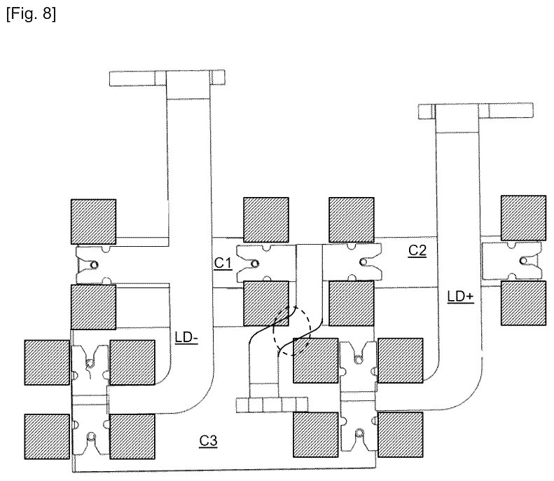

In reference to FIG. 8, if the capacitor C1 was positioned at the same level as the capacitor C2, the elongated body 702 would extend too close to the clamp P1B and/or to the clamp P3A to allow the elements 802, 804 of the tool to pass (see the region inside the dashed line).

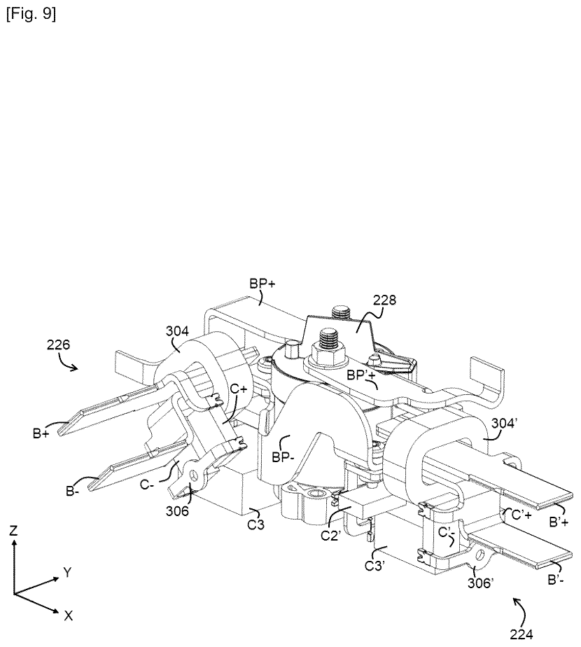

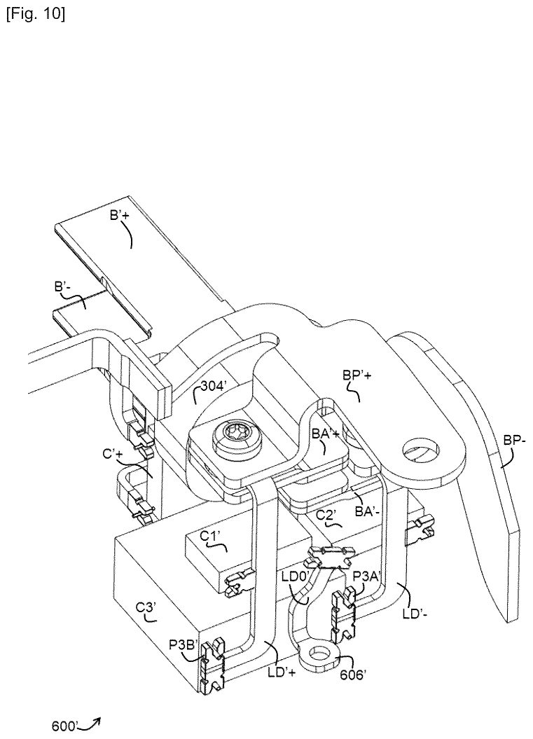

In reference to FIGS. 9 and 10, the input connector 224 has elements similar to those of the output connector 226, for which the reference signs of the preceding figures have been used, with an apostrophe (′) added to distinguish them. The input pins B′+, B′− are identical to the output pins B+, B− and, in particular, have the same shape. The input pins B′+, B′− extend horizontally, i.e., perpendicular to the fixing (for example, screwing) direction. As a result, no angle needs to be compensated for, so the auxiliary busbars BA′+, BA′− are flat.

Furthermore, an electromagnetic compatibility filter 600′ is also provided behind the input connector 224 and has elements similar to those of the electromagnetic compatibility filter 600, for which the reference signs of the preceding figures have been used, with an apostrophe (′) added to distinguish them. In particular, as before, the capacitors C1′, C2′ are vertically offset in order to facilitate the passage of the busbar LD0′ at a distance from the clamp.

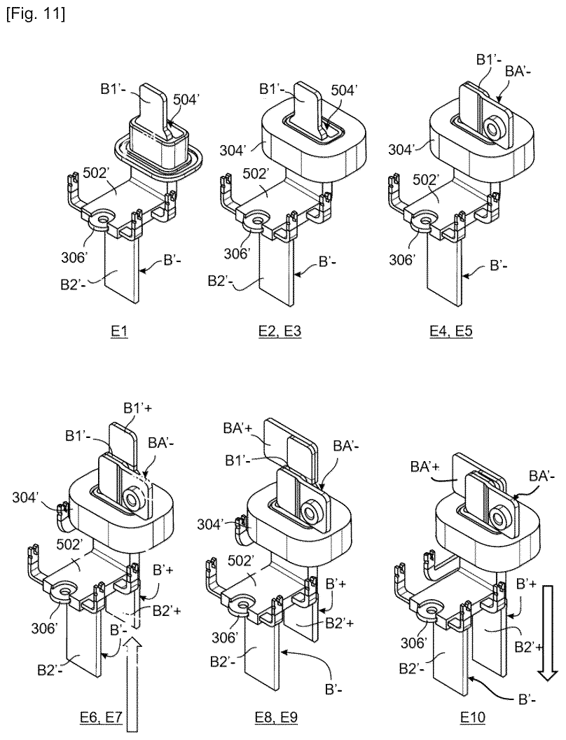

An example of a method for manufacturing the input connector 224 will now be described in reference to FIG. 11.

The output connector 226 is obtained by an identical method.

During a step E1, the negative pin B′− and, for example, the busbar 306′, are obtained. The two are obtained, for example, overmoulded with an overmoulding 502′, leaving the portions B1′−, B2′− of the negative pin B′− exposed. The overmoulding 502′ also has a through-opening 504′ in a part of the overmoulding 502′ that overmoulds the portion B1′− of the negative pin B′−. In other embodiments, the overmoulding 502′ could be devoid of a through-opening 504′.

The magnetic torus 304′ is obtained during a step E2.

During a step E3, the negative pin B′− is inserted into the magnetic torus 304′ by its fixing portion B1′−, for example until the torus 304′ extends around the overmoulding 502′, for example around the part of the overmoulding 302′ that has the through-opening 504′.

The negative auxiliary busbar BA′− is obtained during a step E4.

During a step E5, the portion BA1′− of the negative auxiliary busbar BA′− is pressed and fixed against the fixing portion B1′− of the negative pin B′−. The fixing operation is carried out, for example, by welding, for example by electric brazing and/or by depositing a silver link between the two portions BA1′−, B1′− to be fixed.

The positive branch B′+ comprising the portions B1′+, B2′+ is obtained during a step E6.

During a step E7, the positive pin B′+ is inserted into the torus 304′ by its fixing portion B1′+, offsetting its fixing portion B1′+ from the fixing portion B1′− of the negative pin B′−, for example upwards as in the example shown. In particular, as in the example shown, the positive pin B′+ is inserted into the through-opening 504′ of the overmoulding 502′, such that the torus 304′ surrounds the fixing portion B1′+ of the positive pin B′+.

The positive auxiliary busbar BA′+ is obtained during a step E8.

During a step E9, the portion BA1′+ of the positive auxiliary busbar BA′+ is pressed and fixed against the fixing portion B1′+ of the positive pin B′+. This fixing operation is facilitated by the offset between the fixing portions B1′+, B1′− of the pins B′−, B′+, which allows access from both sides. Fixing is achieved by welding, for example.

During a step E10, the positive pin B′+ is slid downwards into the torus 304′ in order to position the fixing portions B1′+, B1′− opposite each other. For example, as in the example shown, the positive pin B′+ is slid downwards into the through-opening 504′ of the overmoulding 502′.

Once the connector 226 has been obtained by the method for manufacturing a connector as described above, this connector is assembled to the two positive BP+ and negative BP-main busbars of the DC-DC voltage converter 114 according to an assembly method that comprises a step F1 of obtaining a connector 226 according to the method for manufacturing a connector described above, and a step of pressing and fixing the flat portion BP2+ of the positive main busbar BP+ and the flat portion BP2− of the negative main busbar BP− against the respective second flat portions BA2+, BA2− of the auxiliary busbars BA+, BA−.

In particular, this step of pressing and fixing the flat portion BP2+ of the positive main busbar BP+ and the flat portion BP2− of the negative main busbar BP− against the respective second portions BA2+, BA2− of the auxiliary busbars BA+, BA− comprises a step of fixing the second portions BA2+, BA2− of the auxiliary busbars BA+, BA− to the flat portions BP2+, BP2− of the main busbars BP+, BP− by screwing, in a screwing direction that is substantially perpendicular to the second portions BA2+, BA2− of the auxiliary busbars BA+, BA−.

It should also be noted that the invention is not limited to the embodiments described above. Indeed, it will be apparent to a person skilled in the art that various modifications may be made to the embodiments described above, in the light of the teaching that has just been disclosed to them.

In the detailed presentation of the invention that was given above, the terms that were used must not be interpreted as limiting the invention to the embodiments disclosed in the present description, but must be interpreted as including all equivalents conceivable by a person skilled in the art applying her or his general knowledge to the implementation of the teaching that has just been disclosed.

1. Electromagnetic compatibility filter, comprising:
a first conductor;
a second conductor comprising a clamp projecting along an axis referred to as the vertical axis in a direction referred to as the upward direction;
a third conductor comprising:
a first clamp and a second clamp projecting along the same axis referred to as the oblique axis but in opposing directions, the first and second clamps being situated higher than the clamp of the first conductor,
a connection terminal situated lower than the first and second clamps, and
an elongated body connecting the connection terminal to the first and second clamps;
a first capacitor connected between the first conductor and the third conductor, the first capacitor comprising a pin projecting along a first axis substantially perpendicular to the vertical axis and to the oblique axis, this pin of the first capacitor being gripped by the first clamp of the third conductor;
a second capacitor connected between the second conductor and the third conductor, the second capacitor comprising a pin projecting along a second axis substantially parallel to the first axis, this pin of the second capacitor being gripped by the second clamp of the third conductor; and
a third capacitor connected between the first conductor and the second conductor, the third capacitor comprising a pin projecting along a third axis, substantially parallel to the first and second axes, the pin of the third capacitor being gripped by the clamp of the first conductor, the connection terminal of the third conductor being situated lower, in relation to the vertical axis, than this pin of the third capacitor;
wherein the pin of the first capacitor is situated higher, in relation to the vertical axis, than the pin of the second capacitor, so that the oblique axis and the vertical axis form an angle between them of less than 80°, preferably less than 70°, for example 65°.

2. Electromagnetic compatibility filter according to claim 1, in which the capacitors have respective housings of generally parallelepiped shape with top faces perpendicular to the vertical axis, the top face of the first capacitor extending higher than the top face of the second capacitor and the top face of the third capacitor extending below the top face of the second capacitor.

3. Electromagnetic compatibility filter according to claim 1, in which the first capacitor has another pin parallel to the first pin, in which the second capacitor has another pin parallel to the first pin, a first plane defined by the two pins of the first capacitor and a second plane defined by the two pins of the second capacitor being substantially parallel, the first plane extending above the second plane.

4. Electromagnetic compatibility filter according to claim 1, in which the elongated body has a straight end portion from which the clamps of the third conductor project substantially perpendicularly, this straight end portion extending horizontally away from the clamp of the first conductor following this straight end portion from the clamps of the third conductor.

5. Method for manufacturing an electromagnetic compatibility filter according to claim 1, comprising:
obtaining an electromagnetic compatibility filter, comprising:
a first conductor,
a second conductor comprising a clamp projecting along an axis referred to as the vertical axis in a direction referred to as the upward direction,
a third conductor comprising: a first clamp and a second clamp projecting along the same axis referred to as the oblique axis but in opposing directions, the first and second clamps being situated higher than the clamp of the first conductor, a connection terminal situated lower than the first and second clamps, and an elongated body connecting the connection terminal to the first and second clamps,
a first capacitor connected between the first conductor and the third conductor, the first capacitor comprising a pin projecting along a first axis substantially perpendicular to the vertical axis and to the oblique axis,
a second capacitor connected between the second conductor and the third conductor, the second capacitor comprising a pin projecting along a second axis substantially parallel to the first axis,
a third capacitor connected between the first conductor and the second conductor, the third capacitor comprising a pin projecting along a third axis, parallel to the first and second axes, the connection terminal of the third conductor being situated lower, in relation to the vertical axis, than this pin of the third capacitor,
the pin of the first capacitor being situated higher, in relation to the vertical axis, than the pin of the second capacitor, so that the oblique axis and the vertical axis form an angle between them of less than 80°, preferably less than 70°, for example 65°; and
for the clamp of the second conductor, positioning two elements respectively to either side of the clamp, one of the elements extending between the clamp and the elongated body of the third conductor, and using the elements so that the clamp grips the pin of the third capacitor; and
for each of the first and second clamps of the third conductor, positioning two elements respectively to either side of the clamp and using the elements so that the clamp grips the pin of the first capacitor and the pin of the second capacitor respectively.

6. Method according to claim 5, in which using the elements comprises bringing the elements closer to each other.

7. Method according to claim 5, in which using the elements comprises using the elements as electrodes for passing a current through the clamp and the associated pin in order to weld them together.

8. DC-DC electrical converter comprising:
an electrical conversion circuit designed to convert a DC input voltage into a DC output voltage;
an input or output connector, comprising two flat pins, one positive and the other negative, designed to receive the input voltage or to supply the output voltage; and
an electromagnetic compatibility filter according to claim 1, in which the first and second conductors are respectively connected to the two pins, and in which the third connector is connected to an electrical ground.

9. Mobility vehicle comprising an electromagnetic compatibility filter according to claim 1.

10. Electromagnetic compatibility filter according to claim 2, in which the first capacitor has another pin parallel to the first pin, in which the second capacitor has another pin parallel to the first pin, a first plane defined by the two pins of the first capacitor and a second plane defined by the two pins of the second capacitor being substantially parallel, the first plane extending above the second plane.

11. Electromagnetic compatibility filter according to claim 2, in which the elongated body has a straight end portion from which the clamps of the third conductor project substantially perpendicularly, this straight end portion extending horizontally away from the clamp of the first conductor following this straight end portion from the clamps of the third conductor.

12. Method for manufacturing an electromagnetic compatibility filter according to claim 2, comprising:
obtaining an electromagnetic compatibility filter, comprising:
a first conductor,
a second conductor comprising a clamp projecting along an axis referred to as the vertical axis in a direction referred to as the upward direction,
a third conductor comprising: a first clamp and a second clamp projecting along the same axis referred to as the oblique axis but in opposing directions, the first and second clamps being situated higher than the clamp of the first conductor, a connection terminal situated lower than the first and second clamps, and an elongated body connecting the connection terminal to the first and second clamps,
a first capacitor connected between the first conductor and the third conductor, the first capacitor comprising a pin projecting along a first axis substantially perpendicular to the vertical axis and to the oblique axis,
a second capacitor connected between the second conductor and the third conductor, the second capacitor comprising a pin projecting along a second axis substantially parallel to the first axis,
a third capacitor connected between the first conductor and the second conductor, the third capacitor comprising a pin projecting along a third axis, parallel to the first and second axes, the connection terminal of the third conductor being situated lower, in relation to the vertical axis, than this pin of the third capacitor,
the pin of the first capacitor being situated higher, in relation to the vertical axis, than the pin of the second capacitor, so that the oblique axis and the vertical axis form an angle between them of less than 80°, preferably less than 70°, for example 65°; and
for the clamp of the second conductor, positioning two elements respectively to either side of the clamp, one of the elements extending between the clamp and the elongated body of the third conductor, and using the elements so that the clamp grips the pin of the third capacitor; and
for each of the first and second clamps of the third conductor, positioning two elements respectively to either side of the clamp and using the elements so that the clamp grips the pin of the first capacitor and the pin of the second capacitor respectively.

13. Method according to claim 6, in which using the elements comprises using the elements as electrodes for passing a current through the clamp and the associated pin in order to weld them together.

14. DC-DC electrical converter comprising:
an electrical conversion circuit designed to convert a DC input voltage into a DC output voltage;
an input or output connector, comprising two flat pins, one positive and the other negative, designed to receive the input voltage or to supply the output voltage; and
an electromagnetic compatibility filter according to claim 2, in which the first and second conductors are respectively connected to the two pins, and in which the third connector is connected to an electrical ground.

15. Mobility vehicle comprising an electromagnetic compatibility filter according to claim 2.

16. Electromagnetic compatibility filter according to claim 3, in which the elongated body has a straight end portion from which the clamps of the third conductor project substantially perpendicularly, this straight end portion extending horizontally away from the clamp of the first conductor following this straight end portion from the clamps of the third conductor.

17. Method for manufacturing an electromagnetic compatibility filter according to claim 3, comprising:
obtaining an electromagnetic compatibility filter, comprising:
a first conductor,
a second conductor comprising a clamp projecting along an axis referred to as the vertical axis in a direction referred to as the upward direction,
a third conductor comprising: a first clamp and a second clamp projecting along the same axis referred to as the oblique axis but in opposing directions, the first and second clamps being situated higher than the clamp of the first conductor, a connection terminal situated lower than the first and second clamps, and an elongated body connecting the connection terminal to the first and second clamps,
a first capacitor connected between the first conductor and the third conductor, the first capacitor comprising a pin projecting along a first axis substantially perpendicular to the vertical axis and to the oblique axis,
a second capacitor connected between the second conductor and the third conductor, the second capacitor comprising a pin projecting along a second axis substantially parallel to the first axis,
a third capacitor connected between the first conductor and the second conductor, the third capacitor comprising a pin projecting along a third axis, parallel to the first and second axes, the connection terminal of the third conductor being situated lower, in relation to the vertical axis, than this pin of the third capacitor,
the pin of the first capacitor being situated higher, in relation to the vertical axis, than the pin of the second capacitor, so that the oblique axis and the vertical axis form an angle between them of less than 80°, preferably less than 70°, for example 65°; and
for the clamp of the second conductor, positioning two elements respectively to either side of the clamp, one of the elements extending between the clamp and the elongated body of the third conductor, and using the elements so that the clamp grips the pin of the third capacitor; and
for each of the first and second clamps of the third conductor, positioning two elements respectively to either side of the clamp and using the elements so that the clamp grips the pin of the first capacitor and the pin of the second capacitor respectively.

18. DC-DC electrical converter comprising:
an electrical conversion circuit designed to convert a DC input voltage into a DC output voltage;
an input or output connector, comprising two flat pins, one positive and the other negative, designed to receive the input voltage or to supply the output voltage; and
an electromagnetic compatibility filter according to claim 3, in which the first and second conductors are respectively connected to the two pins, and in which the third connector is connected to an electrical ground.

19. Mobility vehicle comprising an electromagnetic compatibility filter according to claim 3.

20. Method for manufacturing an electromagnetic compatibility filter according to claim 4, comprising:
obtaining an electromagnetic compatibility filter, comprising:
a first conductor,
a second conductor comprising a clamp projecting along an axis referred to as the vertical axis in a direction referred to as the upward direction,
a third conductor comprising: a first clamp and a second clamp projecting along the same axis referred to as the oblique axis but in opposing directions, the first and second clamps being situated higher than the clamp of the first conductor, a connection terminal situated lower than the first and second clamps, and an elongated body connecting the connection terminal to the first and second clamps,
a first capacitor connected between the first conductor and the third conductor, the first capacitor comprising a pin projecting along a first axis substantially perpendicular to the vertical axis and to the oblique axis,
a second capacitor connected between the second conductor and the third conductor, the second capacitor comprising a pin projecting along a second axis substantially parallel to the first axis,
a third capacitor connected between the first conductor and the second conductor, the third capacitor comprising a pin projecting along a third axis, parallel to the first and second axes, the connection terminal of the third conductor being situated lower, in relation to the vertical axis, than this pin of the third capacitor,
the pin of the first capacitor being situated higher, in relation to the vertical axis, than the pin of the second capacitor, so that the oblique axis and the vertical axis form an angle between them of less than 80°, preferably less than 70°, for example 65°; and
for the clamp of the second conductor, positioning two elements respectively to either side of the clamp, one of the elements extending between the clamp and the elongated body of the third conductor, and using the elements so that the clamp grips the pin of the third capacitor; and
for each of the first and second clamps of the third conductor, positioning two elements respectively to either side of the clamp and using the elements so that the clamp grips the pin of the first capacitor and the pin of the second capacitor respectively.
